(19) United States
(12) Patent Application Publication
(10) Pub. No.: US 2024/0276835 A1
(43) Pub. Date: Aug. 15, 2024

(54) LIGHT-EMITTING ELEMENT AND DISPLAY DEVICE INCLUDING THE SAME

(71) Applicant: Samsung Display Co., LTD., Yongin-si (KR)

(72) Inventors: SOYOUNG OH, Yongin-si (KR); CHANGYEONG SONG, Yongin-si (KR); JAEHEUNG HA, Yongin-si (KR); YEONGUK KIM, Yongin-si (KR); JONGWOO KIM, Yongin-si (KR); HEEYEON PARK, Yongin-si (KR); HYUNSUP YOON, Yongin-si (KR); WOOSUK JUNG, Yongin-si (KR)

(21) Appl. No.: 18/515,818

(22) Filed: Nov. 21, 2023

(30) Foreign Application Priority Data
Feb. 3, 2023 (KR) 10-2023-0015049

(51) Int. Cl. H10K 59/80

(52) U.S. Cl. CPC H10K 59/80523; H10K 59/873

(57) ABSTRACT

Provided is a display device, including a base layer, and a display element layer on the base layer, and having a light emitting element, the light emitting element includes a first electrode, a second electrode on the first electrode, and a plurality of organic layers between the first electrode and the second electrode, wherein the light emitting element emits light from the first electrode to the second electrode, and the second electrode includes a first layer on the plurality of organic layers, the first layer including silver (Ag) and/or magnesium (Mg), and a second layer on the first layer, the second layer including ytterbium (Yb). Accordingly, the display quality of the display device may be improved.

### CROSS-REFERENCE TO RELATED APPLICATIONS

This application claims priority to and the benefit of Korean Patent Application No. 10-2023-0015049, filed on Feb. 3, 2023, the entire contents of which are hereby incorporated by reference.

### BACKGROUND

### 1. Field

Embodiments of the present disclosure herein relate to a light-emitting element having improved display quality, and a display device including the same.

### 2. Description of the Related Art

An organic light-emitting display device includes an organic light-emitting element including an anode, an organic light-emitting layer, and a cathode. The organic light-emitting element is very vulnerable to moisture and/or oxygen. For example, if moisture and/or oxygen permeates the organic light-emitting display device from the outside, the light-emitting layer may deteriorate, resulting in various failures such as dark spots. Accordingly, an encapsulation substrate is used to protect the light-emitting element.

### SUMMARY

Embodiments of the present disclosure provide a light-emitting element having improved luminescent quality by including a stress-relief structure.

Embodiments of the present disclosure also provide a display device having improved display quality and excellent constant-temperature and constant-humidity characteristics by including a stress-relief structure.

An embodiment of the present disclosure provides a display device including: a base layer; and a display element layer on the base layer and including a light-emitting element, wherein the light-emitting element includes a first electrode, a second electrode on the first electrode, and a plurality of organic layers between the first electrode and the second electrode, the light-emitting element emits light from the first electrode to the second electrode, and the second electrode includes a first layer on the plurality of organic layers, the first layer including silver (Ag) and/or magnesium (Mg); and a second layer on the first layer, the second layer including ytterbium (Yb).

In an embodiment, the second layer may have a thickness of about 5 Å to about 50 Å.

In an embodiment, the second layer may be directly on the first layer.

In an embodiment, the second electrode may further include a lower metal layer under the first layer, and the lower metal layer may include ytterbium (Yb).

In an embodiment, the first layer may include silver (Ag) and magnesium (Mg), and the second layer and the lower metal layer may include ytterbium (Yb).

In an embodiment, the plurality of organic layers may include a hole transport region on the first electrode, a light-emitting layer on the hole transport region, and an electron transport region on the light-emitting layer, and the lower metal layer may be on the electron transport region.

In an embodiment, the light-emitting element may further a capping layer on the second layer.

In an embodiment, the capping layer may include an organic material.

In an embodiment, the capping layer may be directly on the second layer.

In an embodiment, a bonding force between the capping layer and the second layer may be higher than a bonding force between the second layer and the first layer.

In an embodiment, the display device may further include an encapsulation substrate on the display element layer.

In an embodiment, the display device may further include a filling layer between the display element layer and the encapsulation substrate, the filler layer including a filling material.

In an embodiment, the filling material may include a thermosetting resin.

In an embodiment, the display element layer may be divided into an active region and a peripheral region adjacent to the active region, and the filling layer may further include a sealing material which is between the display element layer and the encapsulation substrate to define an inner space, and overlaps the peripheral region.

The filling material may be in the inner space.

In an embodiment of the present disclosure, a light-emitting element includes: a first electrode; a hole transport region on the first electrode; a light-emitting layer on the hole transport region; an electron transport region on the light-emitting layer; and a second electrode on the electron transport region, wherein the second electrode may include a first layer on the electron transport region, the first layer including silver (Ag) and/or magnesium (Mg), and a second layer on the first layer, the second layer may include ytterbium (Yb), and the light-emitting element may emit light from the first electrode to the second electrode.

In an embodiment of the present disclosure, a display device includes: a base layer; a display element layer including a light-emitting element and on the base layer; an encapsulation substrate on the display element layer; and a filling layer including a filling material including a thermosetting resin and between the display element layer and the encapsulation substrate, wherein the light-emitting element includes a first electrode; a second electrode on the first electrode; a plurality of organic layers between the first electrode and the second electrode; and a capping layer on the second electrode, the light-emitting element emits light from the first electrode to the second electrode, the second electrode includes a first layer on the plurality of organic layers, the first layer including silver (Ag) and/or magnesium (Mg), and a second layer between the first layer and the capping layer, and a bonding force between the capping layer and the second layer is higher than a bonding force between the second layer and the first layer.

In an embodiment, a boding force between a lower surface of the capping layer and an upper surface of the second layer may be higher than a bonding force between a lower surface of the second layer and an upper surface of the first layer.

In an embodiment, the second layer may not include metal oxide.

In an embodiment, the second electrode may further include a lower metal layer in the first layer, and the lower metal layer may include a same material as the second layer.

### BRIEF DESCRIPTION OF THE DRAWINGS

The accompanying drawings are included to provide a further understanding of embodiments of the present disclosure, and are incorporated in and constitute a part of this specification. The drawings illustrate example embodiments of the present disclosure and, together with the description, serve to explain principles of the present disclosure. In the drawings:

FIG. 1 is a perspective view of a display device according to one embodiment of the present disclosure;

FIG. 2 is an exploded perspective view of a display device according to one embodiment of the present disclosure;

FIG. 3 is a cross-sectional view of a display device according to one embodiment of the present disclosure;

FIG. 4 is a cross-sectional view of a display panel according to one embodiment of the present disclosure;

FIG. 5 is a cross-sectional view of a light-emitting element according to one embodiment of the present disclosure;

FIG. 6 is a cross-sectional view illustrating a partial configuration of a display panel according to one embodiment of the present disclosure; and

FIG. 7 is a cross-sectional view illustrating an enlarged partial configuration of a display panel according to one embodiment of the present disclosure.

### DETAILED DESCRIPTION

It will be understood that when an element (or a region, layer, portion, or the like) is referred to as being “on”, “connected to”, or “coupled to” another element, it can be directly on or directly connected/coupled to the other element, or a third element may be present therebetween.

Like reference numerals refer to like elements. In the drawings, the thicknesses, ratios, and dimensions of elements may be exaggerated for clarity of illustration. As used herein, the term “and/or” includes any combinations that can be defined by associated elements.

The terms “first”, “second” and the like may be used for describing various elements, but the elements should not be construed as being limited by the terms. Such terms are only used for distinguishing one element from other elements. For example, a first element could be termed a second element and vice versa without departing from the scope of the present disclosure. The terms of a singular form may include plural forms unless otherwise specified.

Furthermore, the terms “under”, “lower side”, “on”, “upper side”, and the like are used to describe association relationships among elements illustrated in the drawings. The terms, which are relative concepts, are used on the basis of directions illustrated in the drawings, but the present disclosure is not limited thereto.

It will be further understood that the terms “include”, “including”, “has”, “having”, and the like, when used in this specification, specify the presence of stated features, numbers, steps, operations, elements, components, or combinations thereof, but do not preclude the presence or addition of one or more other features, numbers, steps, operations, elements, components, or combinations thereof.

All of the terms used herein (including technical and scientific terms) have the same meanings as understood by those skilled in the art, unless otherwise defined. Terms in common usage such as those defined in commonly used dictionaries should be interpreted to contextually match the lexical meanings in the relevant art, and should not be interpreted in an idealized or overly formal sense unless otherwise defined explicitly.

Hereinafter, embodiments of the present disclosure will be described with reference to the accompanying drawings.

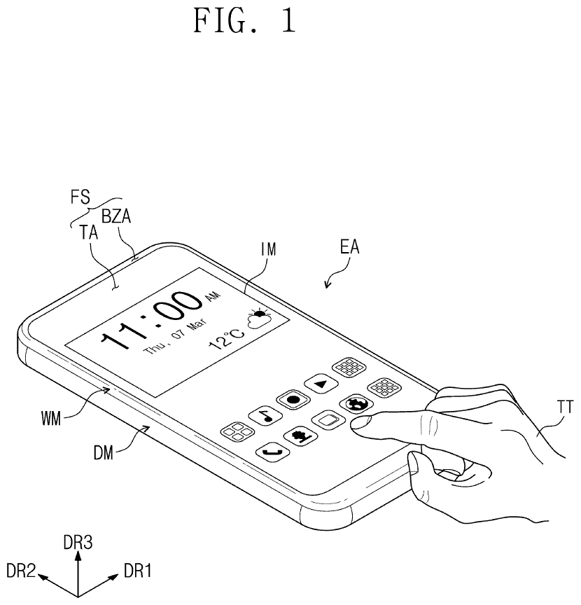

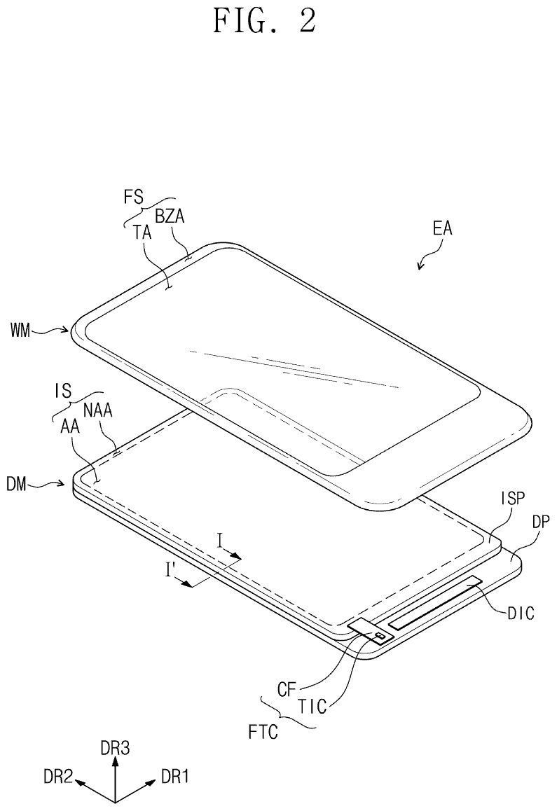

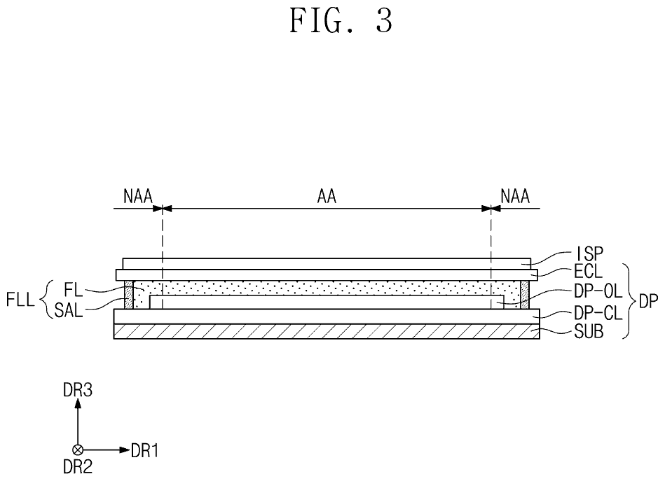

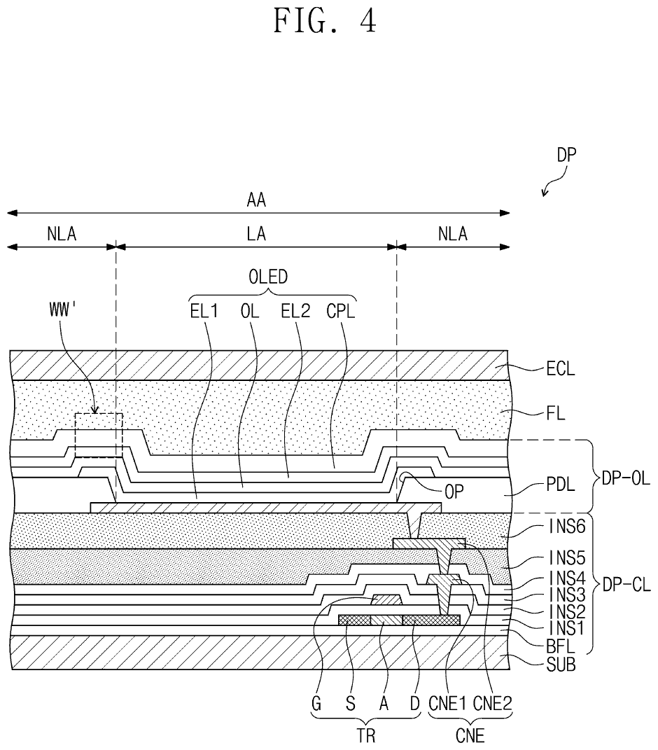

FIG. 1 is a combined perspective view of a display device according to one embodiment of the present disclosure. FIG. 2 is an exploded perspective view of a display device according to one embodiment of the present disclosure. FIG. 3 is a cross-sectional view of a display device according to one embodiment of the present disclosure. FIG. 4 is a cross-sectional view of an active region of a display panel according to one embodiment of the present disclosure.

Referring to FIGS. 1-2, a display device EA may be a device activated according to an electrical signal. The display device EA may include various suitable embodiments. For example, the display device EA may include a tablet PC, a laptop computer, a computer, a smart television, and/or the like. In the present embodiment, the display device EA is illustrated as a smartphone as an example.

The display device EA may display an image IM through a display surface FS. The display surface FS is parallel (or substantially parallel) to a plane defined by a first direction DR1 and a second direction DR2. A third direction DR3 directs a normal direction of the display surface FS, e.g., a thickness direction of the display device EA. A front surface (or an upper surface) and a rear surface (or a lower surface) of each member or unit to be described hereinafter are distinguished based on the third direction DR3.

The display surface FS where the image IM is displayed may correspond to a front surface of the display device EA, and substantially, the display surface FS of the display device EA may correspond to a front surface of a window member WM. Hereinafter, the display surface of the display device EA, the front surface, and the front surface FS of the window member WM are denoted as a like reference numeral or symbol. In FIG. 1, a clock and a plurality of icons are illustrated as one example of the image IM.

The display device EA includes the window member WM and a display module DM. In some embodiments, the display device EA may further include an optical member between the window member WM and the display module DM. The optical member may include a polarizer. The optical member may include a color filter member which reduces an external light reflectance.

The window member WM includes a base panel. For example, the base panel may include glass, plastic, or a combination thereof. The front surface FS of the window member WM includes a transmission region TA and a bezel region BZA. The transmission region TA may be an optically transparent region. For example, the transmission region TA may be a region having a visible light transmittance of about 90% or more.

The bezel region BZA may be a region having a relatively low light transmittance compared to the transmission region TA. The bezel region BZA defines a shape of the transmission region TA. The bezel region BZA may be adjacent to the transmission region TA, and surround the transmission region TA. The window member WM may be in the base panel, and may further include a colored light-blocking pattern that defines the bezel region BZA.

The bezel region BZA may have a set or predetermined color. The bezel region BZA may cover a peripheral region NAA of the display module DM to block the peripheral region NAA from being viewed from the outside. However, this is illustrated as an example, and in the window member WM according to one embodiment of the present disclosure, the bezel region BZA may be omitted.

The display module DM may display the image IM, and sense an external input TT. The image IM may be displayed on a front surface IS of the display module DM. The front surface IS of the display module DM may include an active region AA and a peripheral region NAA. The active region AA may be a region activated according to an electrical signal.

In the present embodiment, the active region AA may be a region where the image IM is displayed, and at the same time, a region where the external input TT is sensed. The active region AA corresponds to the transmission region TA, and the peripheral region NAA corresponds to the bezel region BZA. In this specification, the wording, “a region/part corresponding to a region/part” means “they overlap each other”, and is not limited to having the same area and/or the same shape.

The display module DM includes a display panel DP, a sensing panel ISP, a drive circuit DIC, and a circuit module FTC.

The display panel DP substantially generates the image IM. The display panel DP may be an organic light-emitting display panel and/or a quantum dot light-emitting display panel. These panels are classified based on a constituent material of a light-emitting element. A light-emitting layer of the organic light-emitting display panel may include an organic light-emitting material. A light-emitting layer of the quantum dot light-emitting display panel may include quantum dots and/or quantum rods, etc. Hereinafter, the display panel DP will be described as the organic light-emitting display panel.

The sensing panel ISP senses external inputs (such as a touch event) applied from the outside. In the present embodiment, the sensing panel ISP may be a capacitive type (e.g., a capacitive sensing panel), but an embodiment of the present disclosure is not limited thereto.

The drive circuit DIC is on the display panel DP. The drive circuit DIC may be mounted on the display panel DP. The drive circuit DIC is electrically connected to the display panel DP, and provides the display panel DP with an electrical signal that is for driving the display panel DP.

The circuit module FTC is electrically connected to the sensing panel ISP. In the present embodiment, the circuit module FTC may include a flexible circuit board CF and a sensing drive circuit TIC. The flexible circuit board CF includes lines. The lines electrically connect the sensing panel ISP and the sensing drive circuit TIC. The sensing drive circuit TIC may be mounted and provided on the flexible circuit board CF in the form of a chip-on-film.

The circuit module FTC may connect the sensing panel ISP and the display panel DP. The sensing drive circuit TIC may be omitted. The sensing drive circuit TIC and the drive circuit DIC may be integrated.

Referring to FIG. 3, the display panel DP may include a base layer SUB, a circuit element layer DP-CL, a display element layer DP-OL, a filling layer FLL, and an encapsulation substrate ECL. The sensing panel ISP may be on the encapsulation substrate ECL.

The base layer SUB may include an active region AA and a peripheral region NAA adjacent to the active region AA. The display element layer DP-OL may overlap the active region AA. In the present embodiment, the base layer SUB may be a rigid type (e.g., a rigid base layer). For example, the base layer SUB may include a glass substrate, a metal substrate, a polymer substrate, and/or an organic/inorganic composite material substrate.

The circuit element layer DP-CL is on the base layer SUB. The circuit element layer DP-CL includes at least one insulation layer and a circuit element. The insulation layer includes at least one inorganic film and at least one organic film. The circuit element includes a signal line, a pixel drive circuit, and the like. The circuit element layer DP-CL may be formed through a process of forming an insulation layer, a semiconductor layer, and a conductive layer by coating, deposition, etc., and a process of patterning an insulation layer, a semiconductor layer, and a conductive layer by a photolithography process.

Referring to FIG. 4, a pixel according to the present disclosure may be defined as including a transistor TR and a light-emitting element OLED. The light-emitting element OLED includes a first electrode EL1, a second electrode EL2, and a plurality of organic layers OL. A light-emitting element OLED according to one embodiment may include the plurality of organic layers OL between the first electrode EL1 and the second electrode EL2, and, as described below, the plurality of organic layers OL may include the light-emitting layer, and may further include a hole transport region and an electron transport region.

The transistor TR and the light-emitting element OLED may be on the base layer SUB. Although one transistor TR is illustrated as an example, the pixels PX may include substantially a plurality of the transistors and at least one capacitor that are for driving the light-emitting element OLED.

The active region AA may include a light-emitting region LA corresponding to each of the pixels, and a non-light-emitting region NLA around the light-emitting region LA.

A buffer layer BFL may be on the base layer SUB, and the buffer layer BFL may be an inorganic layer. A semiconductor pattern may be on the buffer layer BFL. The semiconductor pattern may include polysilicon, amorphous silicon, or metal oxide.

The semiconductor pattern may be doped with an N-type dopant or a P-type dopant. The semiconductor pattern may include a heavily doped region and a lightly doped region. A conductivity (e.g., electrical conductivity) of the heavily doped region may be higher than that of the lightly doped region, substantially serving as a source electrode and a drain electrode of the transistor TR. The lightly doped region may substantially correspond to an active (or a channel) of the transistor.

A source S, an active A, and a drain D of the transistor TR may be formed from the semiconductor pattern. A first insulation layer INS1 may be on the semiconductor pattern. A gate G of the transistor TR may be on the first insulation layer INS1. A second insulation layer INS2 may be on the gate G. A third insulation layer INS3 may be on the second insulation layer INS2.

A connection electrode CNE may include a first connection electrode CNE1 and a second connection electrode CNE2 for connecting the transistor TR and the light-emitting element OLED. However, either of the first connection electrode CNE1 or the second connection electrode CNE2 may be omitted. The first connection electrode CNE1 may be on the third insulation layer INS3, and may be connected to the drain D through a first contact hole defined in the first to third insulation layers INS1 to INS3.

A fourth insulation layer INS4 may be on the first connection electrode CNE1. A fifth insulation layer INS5 may be on the fourth insulation layer INS4. The second connection electrode CNE2 may be on the fifth insulation layer INS5. The second connection electrode CNE2 may be connected to the first connection electrode CNE1 through a second contact hole defined in the fourth and fifth insulation layers INS4 and INS5.

A sixth insulation layer INS6 may be on the second connection electrode CNE2. The layers from the buffer layer BFL to the sixth insulation layer INS6 may be defined as the circuit element layer DP-CL. The first insulation layer to the sixth insulation layer INS1, INS2, INS3, INS4, INS5 and INS6 may be inorganic and/or organic layers.

Referring to FIGS. 3-4, the display element layer DP-OL may be on the circuit element layer DP-CL. The display element layer DP-OL may include a plurality of light-emitting elements OLED, and a pixel-defining film PDL.

In one embodiment, the light-emitting element OLED may include the first electrode EL1, the second electrode EL2, and the plurality of organic layers OL. The first electrode EL1 may be on the sixth insulation layer INS6. The first electrode EL1 may be connected to the second connection electrode CNE2 through a third contact hole defined in the sixth insulation layer INS6. On the first electrode EL1 and the sixth insulation layer INS6, the pixel-defining film PDL in which an opening OP for exposing a set or predetermined portion of the first electrode EL1 is defined may be provided. In the present embodiment, the light-emitting region LA may correspond to an area of the first electrode EL1 that is exposed by the opening OP, and a non-light-emitting region NLA may correspond to a region overlapping the pixel-defining film PDL.

The plurality of organic layers OL may be on the first electrode EL1. The plurality of organic layers OL may be in a region corresponding to the opening OP. The plurality of organic layers OL may include a light-emitting layer including an organic material and/or an inorganic material, and the light-emitting layer may generate light of any one selected from among red color, green color, or blue color.

The second electrode EL2 may be on the plurality of organic layers OL. The second electrode EL2 may be in common in the pixels. Therefore, the second electrode EL2 may be entirely in the light-emitting region LA and the non-light-emitting region NLA. In the present embodiment, a layer in which the light-emitting element OLED is may be defined as the display element layer DP-OL.

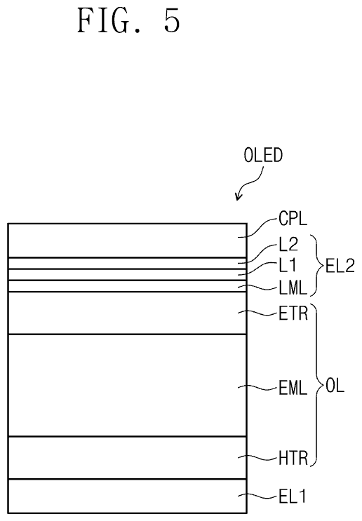

A first voltage may be applied to the first electrode EL1 via the transistor TR, and a second voltage may be applied to the second electrode EL2. The light-emitting element OLED may emit light when excitons formed through combination of holes and electrons injected into the light-emitting layer EML (see FIG. 5) of the plurality of organic layers OL transit to a ground state.

The light-emitting element OLED according to an embodiment of the present disclosure may further include a capping layer CPL. The capping layer CPL may cover the second electrode EL2, and may, like the second electrode EL2, be entirely in the light-emitting region LA and the non-light-emitting region NLA. The capping layer CPL may include an organic material, and may have a greater thickness than the second electrode EL2.

In one embodiment, the encapsulation substrate ECL may oppose the base layer SUB and cover the display element layer DP-OL. The encapsulation substrate ECL according to an embodiment may include a glass substrate, a metal substrate, a polymer substrate, and/or an organic/inorganic composite material substrate. The encapsulation substrate ECL and the filling layer FLL may prevent or reduce permeation of moisture into the display element layer DP-OL.

The filling layer FLL may be on the display element layer DP-OL and cover the pixels. The filling layer FLL may include a filling material FL and a sealing material SAL.

The filling material FL may be between the capping layer CPL and the encapsulation substrate ECL. The filling material FL may be in contact with an upper surface of the capping layer CPL and a lower surface of the encapsulation substrate ECL. In the specification, “the lower surface of the encapsulation substrate ECL” may be defined as a surface, of the encapsulation substrate ECL, facing the display element layer DP-OL. For example, in an embodiment, the encapsulation substrate ECL may be on the filling material FL.

In one embodiment, the sealing material SAL may be between the encapsulation substrate ECL and the base layer SUB. The sealing material SAL may be on the circuit element layer DP-CL, and may overlap the peripheral region NAA. In a plan view, the sealing material SAL may have a closed loop shape surrounding the active region AA. The encapsulation substrate ECL and the base layer SUB may be bonded by the sealing material SAL. The sealing material SAL may include an inorganic adhesive layer such as a frit. However, an embodiment of the present disclosure is not limited thereto, and the sealing material SAL may include an organic adhesive layer. In the present embodiment, as the sealing material SAL and the filling material FL are provided, the encapsulation substrate ECL and the base layer SUB may be completely sealed, and thus planarize components in the display panel DP, and a defect of the display element layer DP-OL may be prevented (or a likelihood or occurrence of such a defect may be reduced).

The filling material FL may be filled in an inner space defined by the base layer SUB, the encapsulation substrate ECL and the sealing material SAL. The filling material FL may include a curable material. For example, the filling material FL may include a thermosetting resin. The filling material FL may include silicon-based, epoxy-based, and/or acrylic-based thermosetting materials. However, a material of the filling material FL is not limited to the examples above. A viscosity of the filling material FL may be about 3000 cps to about 40000 cps.

FIG. 5 is a cross-sectional view schematically illustrating a light-emitting element according to an embodiment of the present disclosure.

A light-emitting element OLED includes a first electrode EL1, a plurality of organic layers OL and a second electrode EL2. The light-emitting element OLED may further include a capping layer CPL on the second layer L2.

The first electrode El1 has conductivity (e.g., electrical conductivity). The first electrode El1 may be formed of a metal material, a metal alloy, and/or a conductive compound (e.g., an electrically conductive compound). The first electrode EL1 may be an anode or cathode. However, an embodiment of the present disclosure is not limited thereto. Furthermore, the first electrode EL1 may be a pixel electrode. The first electrode EL1 may be a transmissive electrode, a transflective electrode, or a reflective electrode. The first electrode EL1 may include at least one selected from among Ag, Mg, Cu, Al, Pt, Pd, Au, Ni, Nd, Ir, Cr, Li, Ca, LiF, Mo, Ti, W, In, Sn, and Zn, a compound of two or more selected from thereamong, a mixture of two or more selected from thereamong them, and/or an oxide thereof.

When the first electrode EL1 is a transmissive electrode, the first electrode EL1 may include a transparent metal oxide, such as indium tin oxide (ITO), indium zinc oxide (IZO), zinc oxide (ZnO), indium tin zinc oxide (ITZO). When the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/AI (a stacked structure of LiF and Al), Mo, Ti, W and/or a compound thereof or a mixture thereof (e.g., a mixture of Ag and Mg). In some embodiments, the first electrode EL1 may be a multilayer structure including a reflective layer or transflective layer formed of the aforementioned materials and a transparent conductive layer formed of indium tin oxide (ITO), indium zinc oxide (IZO), zinc oxide (ZnO), indium tin zinc oxide (ITZO) and/or the like. For example, the first electrode EL1 may have a three-layer structure of ITO/Ag/ITO, but an embodiment of the present disclosure is not limited thereto. Furthermore, an embodiment of the present disclosure is not limited thereto, and the first electrode EL1 may include the aforementioned metal materials, a combination of two or more metal materials selected from among the aforementioned metal materials, oxides of the aforementioned metal materials, and/or the like. The first electrode EL1 may have a thickness of about 700 Å to about 10000 Å. For example, the first electrode EL1 may have a thickness of about 1000 Å to about 3000 Å.

The plurality of organic layers OL may be between the first electrode EL1 and the second electrode EL2. The plurality of organic layers OL may include a hole transport region HTR on the first electrode EL1, a light-emitting layer EML on the hole transport region HTR, and an electron transport region ETR on the light-emitting layer EML.

The hole transport region HTR may be provided on the first electrode EL1. The hole transport region HTR may include at least one selected from a hole injection layer, a hole transport layer, a buffer layer and/or a light-emitting auxiliary layer, and/or an electron blocking layer. The hole transport region HTR may have a thickness of about 50 Å to about 15,000 Å.

The hole transport region HTR may have a single layer including a single material, a single layer including a plurality of different materials, or a multi-layer structure having a plurality of layers including a plurality of different materials.

For example, the hole transport region HTR may have a single-layer structure of the hole injection layer or the hole transport layer, or may have a single-layer structure including a hole injection material and a hole transport material. In addition, the hole transport region HTR may have a single-layer structure including a plurality of different materials, or may have a structure of the hole injection layer/the hole transport layer, the hole injection layer/the hole transport layer/the buffer layer, the hole injection layer/the buffer layer, the hole transport layer/the buffer layer, or the hole injection layer/the hole transport layer/the electron blocking layer which are sequentially stacked from the first electrode EL1, but an embodiment of the present disclosure is not limited thereto.

The hole transport region HTR may be formed using various suitable methods such as a vacuum deposition method, a spin coating method, a casting method, a Langmuir-Blodgett (LB) method, an inject printing method, a laser printing method, and/or a laser induced thermal imaging (LITI) method.

The light-emitting layer EML is provided on the hole transport region HTR. The light-emitting layer EML may have a thickness of, for example, about 100 Å to about 1000 Å, or about 100 Å to about 300 Å. The light-emitting layer EML may have a single layer including a single material, a single layer including a plurality of different materials, or a multi-layer structure having a plurality of layers including a plurality of different materials.

In the light-emitting element OLED according to an embodiment, the light-emitting layer EML may include anthracene derivatives, pyrene derivatives, fluoranthene derivatives, chrysene derivatives, dihydrobenzanthracene derivatives, and/or triphenylene derivatives. For example, the light-emitting layer EML may include anthracene derivatives and/or pyrene derivatives.

The electron transport region ETR may have a single layer including a single material, a single layer including a plurality of different materials, or a multi-layered structure having a plurality of layers including a plurality of different materials.

For example, the electron transport region ETR may have a single-layer structure of an electron injection layer or an electron transport layer, or may have a single-layer structure including an electron injection material and an electron transport material. In addition, the electron transport region ETR may have a single-layer structure including a plurality of different materials, or may have a structure of the electron transport layer/the electron injection layer, a hole blocking layer/the electron transport layer/the electron injection layer which are sequentially stacked from the light-emitting layer EML, but an embodiment of the present disclosure is not limited thereto. The electron transport region ETR may have a thickness of, for example, about 1000 Å to about 1500 Å.

The electron transport region ETR may be formed using various suitable methods such as a vacuum deposition method, a spin coating method, a casting method, a Langmuir-Blodgett (LB) method, an inject printing method, a laser printing method, and/or a laser induced thermal imaging (LITI) method.

The second electrode EL2 may be provided on the electron transport region ETR. The second electrode EL2 may be a cathode or an anode, but an embodiment of the present disclosure is not limited thereto. For example, when the first electrode EL1 is an anode, the second electrode EL2 may be a cathode; and when the first electrode EL1 is a cathode, the second electrode EL2 may be an anode.

The second electrode EL2 may be a transmissive electrode, a transflective electrode, or a reflective electrode. When the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/AI, Mo, Ti, Yb, W and/or a compound or a mixture including the same. For example, the second electrode EL2 may include AgMg, AgYb, and/or MgYb. In some embodiments, the second electrode EL2 may be a multilayer structure including a reflective film or a transflective film including the aforementioned material and a transparent conductive film including indium tin oxide (ITO), indium zinc oxide (IZO), zinc oxide (ZnO), indium tin zinc oxide (ITZO) and/or the like. The second electrode EL2 may have a thickness of about 700 Å to about 1000 Å. For example, the second electrode EL2 may have a thickness of about 1000 Å to about 3000 Å.

The second electrode EL2 includes a first layer L1 and a second layer L2 on the first layer L1. The second layer L2 may be on the first layer L1 in a direction in which light generated in the light-emitting element OLED is emitted. The second layer L2 may be directly on the first layer L1.

A material included in the first layer L1 may be different from a material included in the second layer L2. Each of the first layer L1 and the second layer L2 may include the aforementioned metal material, or a combination of two or more metal materials selected from among the aforementioned metal materials. The second layer L2 may not include an oxide of the aforementioned metal material. The first layer L1 includes silver (Ag) and/or magnesium (Mg), and the second layer L2 includes ytterbium (Yb). For example, the first layer L1 may include AgMg, and the second layer L2 may include ytterbium (Yb).

In one embodiment, the second electrode EL2 may further include a lower metal layer LML under the first layer L1. A material included in the lower metal layer LML may be the same as a material included in the second layer L2. For example, the second layer L2 and the lower metal layer LML may each include ytterbium (Yb).

The capping layer CPL may be on the second electrode EL2 of the light-emitting element OLED according to an embodiment. The capping layer CPL may include a plurality of layers or a single layer.

In one embodiment, the capping layer CPL may be an organic layer. For example, the capping layer CPL may include α-NPD, NPB, TPD, m-MTDATA, Alq3, CuPc, TPD15(N4,N4,N4′,N4′-tetra(biphenyl-4-yl) biphenyl-4,4′-diamine), TCTA (4,4′,4″-tris(carbazol sol-9-yl) triphenylamine) and/or the like, and/or may include epoxy resin and/or acrylate such as methacrylate. However, an embodiment of the present disclosure is not limited thereto, and the capping layer CPL may include at least one selected from among compounds P1 to P5 below.

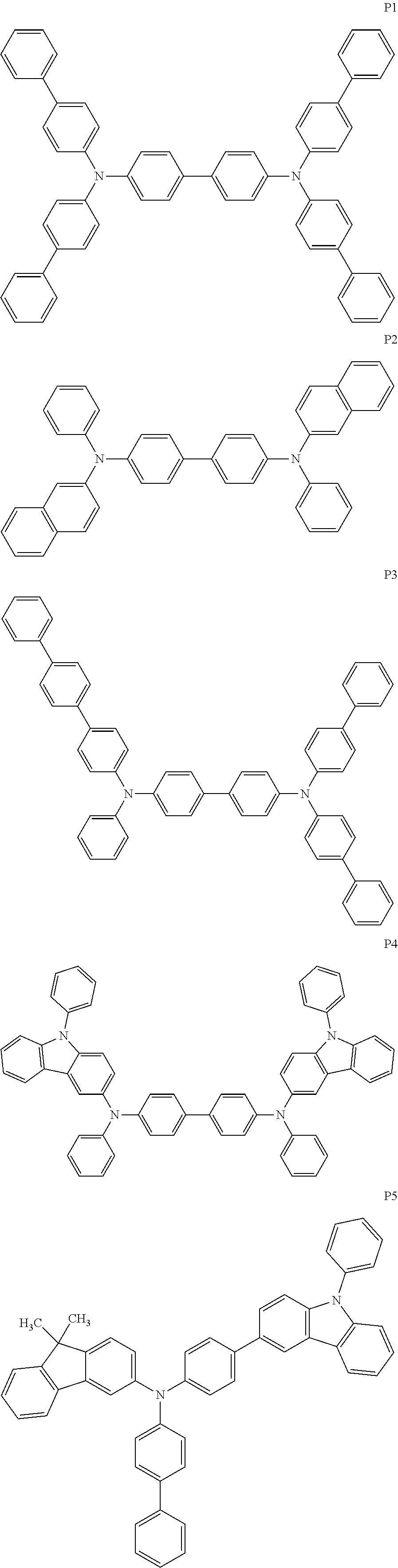 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

In some embodiments, the capping layer CPL may have a refractive index of about 1.6 or more. For example, the capping layer CPL may have a refractive index of about 1.6 or more for light in a wavelength in a range from about 550 nm to 660 nm.

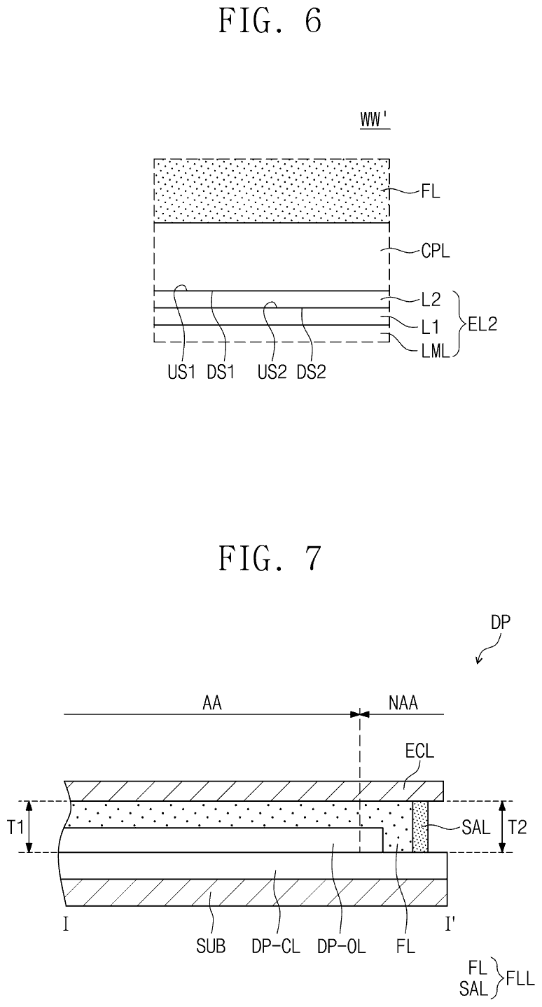

FIG. 6 is a cross-sectional view schematically illustrating a partial configuration of a display panel according to an embodiment. FIG. 6 illustrates an enlarged cross-section corresponding to WW′ region of FIG. 4. For example, FIG. 6 illustrates a stacked structure of a second electrode EL2, a capping layer CPL and a filling material FL.

Referring to FIG. 6, the second electrode EL2 may include a first layer L1, a second layer L2 on the first layer L1, and a lower metal layer LML under the first layer L1. The second electrode EL2 may include the first layer L1, the second layer L2, and the lower metal layer LML. The second layer L2 may be directly on the first layer L1, and thus a lower surface DS2 of the second layer L2 and an upper surface US2 of the first layer may be in contact with each other. The second layer L2 may include ytterbium (Yb). The second layer L2 may not include a metal oxide. For example, the second layer L2 may include ytterbium (Yb). The second layer L2 may have a thickness of about 5 Å to about 50 Å. For example, the second layer L2 may have a thickness of about 10 Å to about 20 Å.

The capping layer CPL may include an organic material. The capping layer CPL may be on the second layer L2. The capping layer CPL may be directly on the second layer L2, and thus a lower surface DS1 of the capping layer CPL and an upper surface US1 of the second layer L2 may be in contact with each other.

A bonding force between the capping layer CPL and the second layer L2 may be greater than a bonding force between the second layer L2 and the first layer L1. For example, a bonding force between the lower surface DS1 of the capping layer CPL and the upper surface US1 of the second layer L2 may be greater than a bonding force between the lower surface DS2 of the second layer L2 and the upper surface US2 of the first layer L1.

The filling material FL may be on the capping layer CPL. The filling material FL may be directly on the capping layer CPL. The filling material FL may include a thermosetting resin. The filling material FL may be provided through a process of applying a thermosetting resin and a process of curing the thermosetting resin. Due to contraction and/or expansion occurring in the thermosetting resin included in the filling material FL in the curing process, stress may be applied to a plurality of members under the filling material FL. For example, because a thermal curing process is included in manufacturing of the filling material FL according to an embodiment of the present disclosure, stress may be applied to the capping layer CPL or the second electrode EL2 which is under the filling material FL.

In a display device including a light-emitting element, an encapsulation substrate is provided for constant temperature and constant humidity, and a filling material including a curable resin and the like is provided for attachment of the encapsulation substrate. In other display devices, stress is applied to a second electrode due to the thermal curing process in manufacturing of a filling material, thereby resulting in deterioration in display quality and deterioration in moisture permeation prevention or reduction because the second electrode is short-circuited. However, a display device according to an embodiment of the present disclosure includes, in a second electrode, a second layer that performs a stress-relief function, and thus prevents or reduces peel-off caused by the stress. Even when the stress is generated due to contraction or expansion in the manufacturing of the filling material, the second layer between the filling material and the first layer reduces the stress, and therefore peel-off of the first layer is prevented or reduced, thereby preventing short-circuiting of the second electrode (or reducing a likelihood or occurrence of such short-circuiting). Furthermore, because a bonding force between the second layer and the first layer is relatively weak compared to a bonding force between a capping layer and the second layer, peel-off may not occur in the first layer under the second layer, thereby preventing short-circuiting of the second electrode (or reducing a likelihood or occurrence of such short-circuiting). Because the light-emitting element according to an embodiment of the present disclosure includes the second layer in the second electrode, and has the first layer of which a bonding force to the second layer is weak, an incidence of dark spots within the light-emitting element may decrease. Accordingly, the display quality of a display device including the light-emitting element may be improved.

FIG. 7 is an enlarged cross-sectional view illustrating a partial configuration of a display panel according to an embodiment. FIG. 7 is a cross-sectional view merely illustrating only a partial configuration of the display panel DP of a cross section taken along line I-I′ of FIG. 2. FIG. 7 enlarges and illustrates an encapsulation substrate ECL, a filling layer FLL, a display element layer DP-OL, and a circuit element layer DP-CL. For example, FIG. 7 illustrates the filling layer FLL in an active region AA and a peripheral region NAA of the display panel DP.

Referring to FIG. 7, the encapsulation substrate ECL and a base layer SUB may be bonded by a sealing material SAL in the filling layer FLL. A method of manufacturing a display device EA (see FIG. 2) according to an embodiment may include, after forming the circuit element layer DP-CL and the display element layer DP-OL on the base layer SUB, a process of bonding the sealing material SAL and the filling material FL attached to the encapsulation substrate ECL to the circuit element layer DP-CL and the base layer SUB (see FIG. 2). Due to the bonding process, a thickness T2 of the filling material FL overlapping a peripheral region NAA may be smaller than a thickness T1 of the filling material FL overlapping an active region AA. Accordingly, the intensity of stress occurring in a plurality of films under the filling material FL overlapping the peripheral region NAA may become relatively high compared to the filling material FL overlapping the active region AA. Therefore, in an embodiment, because the second layer L2 (see FIG. 6) is provided on the first layer L1 (see FIG. 6), the quality and reliability of the second electrode EL2 (see FIG. 6) overlapping the peripheral region NAA may be further improved.

A light-emitting element according to the present disclosure includes a second electrode having a second layer of a stress-relief layer, and may thus achieve an effect of improving reliability. Because the light-emitting element according to the present disclosure includes the light-emitting element, occurrence of dark spots may be prevented or reduced, thereby making it possible to provide a display device having improved display quality and reliability.

Although example embodiments of the present disclosure have been described, it is understood that the present disclosure should not be limited to these example embodiments but various changes and modifications can be made by one ordinary skilled in the art within the spirit and scope of the present disclosure.

Therefore, a technical scope of the present disclosure is not limited to the content described in the detailed description of the specification, but is determined by the appended claims, and equivalents thereof.

What is claimed is:

1. A display device comprising:
a base layer; and
a display element layer on the base layer, and comprising a light emitting element,
wherein the light emitting element comprises a first electrode, a second electrode on the first electrode, and a plurality of organic layers between the first electrode and the second electrode,
the light emitting element emits light from the first electrode to the second electrode, and
the second electrode comprises:
a first layer on the plurality of organic layers, the first layer comprising silver (Ag) and/or magnesium (Mg); and
a second layer on the first layer, the second layer comprising ytterbium (Yb).

2. The display device of claim 1, wherein the second layer has a thickness of about 5 Å to about 50 Å.

3. The display device of claim 1, wherein the second layer is directly on the first layer.

4. The display device of claim 1, wherein the second electrode further comprises a lower metal layer under the first layer, and
the lower metal layer comprises ytterbium (Yb).

5. The display device of claim 4, wherein the first layer comprises silver (Ag) and magnesium (Mg), and
the second layer and the lower metal layer comprise ytterbium (Yb).

6. The display device of claim 4, wherein the plurality of organic layers comprise a hole transport region on the first electrode, a light-emitting layer on the hole transport region, and an electron transport region on the light-emitting layer, and
the lower metal layer is on the electron transport region.

7. The display device of claim 1, wherein the light emitting element further comprises a capping layer on the second electrode.

8. The display device of claim 7, wherein the capping layer comprises an organic material.

9. The display device of claim 7, wherein the capping layer is directly on the second layer.

10. The display device of claim 7, wherein a bonding force between the capping layer and the second layer is higher than a bonding force between the second layer and the first layer.

11. The display device of claim 1, further comprising an encapsulation substrate on the display element layer.

12. The display device of claim 11, further comprising a filling layer between the display element layer and the encapsulation substrate, and comprising a filling material.

13. The display device of claim 12, wherein the filling material comprises a thermosetting resin.

14. The display device of claim 12, wherein the display element layer is divided into an active region and a peripheral region adjacent to the active region, and
the filling layer further comprises a sealing material which is between the display element layer and the encapsulation substrate to define an inner space, and overlaps the peripheral region.

15. The display device of claim 14, wherein the filling material is in the inner space.

16. A light emitting element comprising:
a first electrode;
a hole transport region on the first electrode;
a light-emitting layer on the hole transport region;
an electron transport region on the light-emitting layer; and
a second electrode on the electron transport region,
wherein the second electrode comprises a first layer on the electron transport region, the first layer comprising silver (Ag) and/or magnesium (Mg), and a second layer on the first layer,
the second layer comprises ytterbium (Yb), and
the light emitting element emits light from the first electrode to the second electrode.

17. A display device comprising:
a base layer;
a display element layer comprising a light emitting element, and on the base layer;
an encapsulation substrate on the display element layer; and
a filling layer comprising a filling material having a thermosetting resin, and between the display element layer and the encapsulation substrate,
wherein the light emitting element comprises:
a first electrode;
a second electrode on the first electrode;
a plurality of organic layers between the first electrode and the second electrode; and
a capping layer on the second electrode,
the light emitting element emits light from the first electrode to the second electrode,
the second electrode comprises a first layer on the plurality of organic layers, the first layer comprising silver (Ag) and/or magnesium (Mg), and a second layer between the first layer and the capping layer, and
a bonding force between the capping layer and the second layer is higher than a bonding force between the second layer and the first layer.

18. The display device of claim 17, wherein a bonding force between a lower surface of the capping layer and an upper surface of the second layer is higher than a bonding force between a lower surface of the second layer and an upper surface of the first layer.

19. The display device of claim 17, wherein the second layer does not comprise metal oxide.

20. The display device of claim 17, wherein the second electrode further comprises a lower metal layer in the first layer, and
the lower metal layer comprises a same material as the second layer.
